(19) United States
(12) Patent Application Publication
(10) Pub. No.: US 2008/0029833 A1
(43) Pub. Date: Feb. 7, 2008

(54) TRANSISTOR, AN ELECTRONIC CIRCUIT AND AN ELECTRONIC DEVICE

(75) Inventor: Shunp LI, Cambridge (GB)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 11/828,057

(22) Filed: Jul. 25, 2007

(30) Foreign Application Priority Data
Aug. 2, 2006 (JP) 2006-210595

(51) Int. Cl. H01L 29/78

(52) U.S. Cl. 257/410; 257/288; 257/E29.255; 257/E29.273

(57) ABSTRACT

A method of fabricating a TFT, including: (a) forming a gate electrode on a predetermined portion of an underlying layer, (b) covering the gate electrode with a dielectric layer so that the dielectric layer defines two indented regions and a protruding region that separate the two indented regions from each other, (c) making a top surface of the protruding region oleophobic or hydrophobic, (d) providing a functional liquid containing a conductive material in the two indented regions after step (c), (e) heating or drying the functional liquid so as to form a source electrode and a drain electrode containing the conductive material; and (f) forming a semiconductor layer that is electrically coupled with the source electrode and the drain electrode.

The entire disclosure of Japanese Patent Application No. 2006-210595, filed on Aug. 2, 2006, is expressly incorporated by reference herein.

### BACKGROUND

1. Technical Field

Several aspects of the invention relate to a transistor fabrication method, especially to one in which a so-called liquid process is preferably utilized, and to a transistor fabricated by such a method.

2. Related Art

Printing technologies such as screen printing are utilized in fabricating organic transistors.

### SUMMARY

A so-called liquid process is useful for reducing the number of photolithography processes involved in the fabrication of TFTs (thin film transistors). The liquid process reduces the number of photolithography processes, which require an expensive exposure apparatus, thus lowering the cost of TFT fabrication.

In the liquid process, a material used for a gate electrode, a source electrode or a drain electrode is included in a liquid and is deposited on underlying surfaces. However, since the liquid spreads over the surfaces, it is difficult to establish an accurate alignment between these electrodes. The gate electrode and the source/drain electrodes may thus improperly overlap. This inappropriate overlap yields high parasitic capacitance between the gate electrode and the source or drain electrode, degrading the performance of the TFTs.

One objective of an aspect of the invention is to provide a technology that facilitates the TFT fabrication while using the liquid process.

According to an aspect of the invention, a method of fabricating a TFT includes (a) forming a gate electrode on a predetermined portion of an underlying layer, (b) covering the gate electrode with a dielectric layer so that the dielectric layer defines two indented regions and a protruding region that separates the two indented regions from each other, (c) making a top surface of the protruding region oleophobic or hydrophobic, (d) providing a functional liquid containing a conductive material in the two indented regions after step (c), (e) heating or drying the functional liquid so as to form a source electrode and a drain electrode containing the conductive material; and (f) forming a semiconductor layer that is electrically coupled with the source electrode and the drain electrode.

Preferably, step (c) includes forming an oleophobic or hydrophobic layer on the top surface of the protruding region by soft contact printing.

The oleophobic or hydrophobic layer may be a self-assembled molecular layer.

The oleophobic or hydrophobic layer may contain a polymer containing fluorine.

According to another aspect of the invention, a method of fabricating a TFT includes (a) forming a source electrode and a drain electrode on respective portions of an underlying layer, (b) forming a semiconductor layer that is electrically coupled with the source electrode and the drain electrode and that defines two protrusions and an indentation that separates the two protrusions from each other, (c) forming a dielectric layer on the semiconductor layer so that the dielectric layer defines two protruding regions and an indented region respectively corresponding to the two protrusions and the indentation, (d) making top surfaces of the two protruding regions oleophobic or hydrophobic, (e) providing a functional liquid containing a conductive material in the indented regions after step (d); and (f) heating or drying the functional liquid so as to form a gate electrode containing the conductive material.

Preferably, step (d) includes forming oleophobic or hydrophobic layers on the top surfaces by soft contact printing.

Each of the oleophobic or hydrophobic layers may be a self-assembled molecular layer.

The oleophobic or hydrophobic layers may contain a polymer containing fluorine.

According to another aspect of the invention, a method of fabricating a TFT includes (a) embossing an upper layer of a multi-layer structure including the upper layer and a lower layer so that a first tapered protrusion is defined by the upper layer,

(b) etching the lower layer through the upper layer so that a second tapered protrusion corresponding to the first tapered protrusion is defined by the lower layer, (c) forming a gate electrode along the second tapered protrusion, (d) forming a dielectric layer along the gate electrode so as to form a third tapered protrusion of the dielectric layer on the gate electrode, (e) making a top surface of the third tapered protrusion oleophobic or hydrophobic, (f) providing a functional liquid containing a conductive material in regions separated by the third tapered protrusion so that the functional liquid comes into contact with two slopes of the third tapered protrusion after step (e), the two slopes facing opposite sides to each other, (g) heating or drying the functional liquid so as to form a source electrode and a drain electrode containing the conductive material; and (h) forming a semiconductor layer that is electrically coupled with the source electrode and the drain electrode.

Preferably, step (e) includes forming an oleophobic or hydrophobic layer on the top surface of the third tapered protrusion by soft contact printing.

The oleophobic or hydrophobic layer may be a self-assembled molecular layer.

The oleophobic or hydrophobic layer may contain a polymer containing fluorine.

According to another aspect of the invention, a TFT has an underlying layer, a gate electrode located on the underlying layer, a dielectric layer covering the gate electrode so as to define two indented regions and a protruding region separating the two indented regions from each other, an oleophobic or hydrophobic layer formed on a top surface of the protruding region, a source electrode and a drain electrode formed in the two indented regions; and a semiconductor layer that is electrically coupled with the source electrode and the drain electrode.

Preferably, the source electrode and the drain electrode are formed by providing a functional liquid containing a conductive material in the two indented regions and heating or drying the functional liquid in the two indented regions.

The oleophobic or hydrophobic layer may be a self-assembled molecular layer.

The oleophobic or hydrophobic layer may contain a polymer containing fluorine.

According to another aspect of the invention, an electronic circuit has the above-mentioned TFT.

According to another aspect of the invention, an electronic device has the above-mentioned TFT.

According to another aspect of the invention, an electronic apparatus has the above-mentioned TFT.

According to another aspect of the invention, a TFT has an underlying layer, a source electrode and a drain electrode located on the underlying layer, a semiconductor layer that is electrically coupled with the source electrode and the drain electrode and that defines two protrusions and an indentation, a dielectric layer formed on the semiconductor layer so as to define two protruding regions and an indented region respectively corresponding to the two protrusions and the indentation, oleophobic or hydrophobic layers formed on top surfaces of the two protruding regions; and a gate electrode formed in the indented region.

Preferably, the gate electrode is formed by providing a functional liquid containing a conductive material in the indented region and heating or drying the functional liquid in the two indented regions.

Each of the oleophobic or hydrophobic layers may be a self-assembled molecular layer.

The oleophobic or hydrophobic layers may contain a polymer containing fluorine.

According to another aspect of the invention, an electronic circuit has the above-mentioned TFT.

According to another aspect of the invention, an electronic device has the above-mentioned TFT.

According to another aspect of the invention, an electronic apparatus has the above-mentioned TFT.

According to another aspect of the invention, a TFT has an underlying layer, a first tapered protrusion located on the underlying layer, a gate electrode formed along the first tapered protrusion, a dielectric layer covering the gate electrode so as to define a second tapered protrusion, an oleophobic or hydrophobic layer formed on a top surface of the second tapered protrusion, a source electrode and a drain electrode formed so as to be in contact with respective two slopes of the second tapered protrusion, the two slopes facing opposite sides to each other; and a semiconductor layer that is electrically coupled with the source electrode and the drain electrode.

Preferably, the source electrode and the drain electrode are formed by providing a functional liquid containing a conductive material in the two regions separated by the second tapered protrusion and heating or drying the functional liquid in the two regions.

The oleophobic or hydrophobic layer may be a self-assembled molecular layer.

The oleophobic or hydrophobic layer may contain a polymer containing fluorine.

According to another aspect of the invention, an electronic circuit has the above-mentioned TFT.

According to another aspect of the invention, an electronic device has the above-mentioned TFT.

According to another aspect of the invention, an electronic apparatus has the above-mentioned TFT.

### BRIEF DESCRIPTION OF THE DRAWINGS

FIG. 1 is a schematic diagram illustrating a cross-section of a TFT in embodiment 1.

FIGS. 2A to 2D illustrate a method of fabricating the TFT in embodiment 1.

FIGS. 3A to 3D illustrate the method of fabricating the TFT in embodiment 1.

FIGS. 4A and 4B illustrate the method of fabricating the TFT in embodiments.

FIG. 5 shows the top surface of the TFT in embodiment 1.

FIG. 6 is a schematic diagram illustrating a cross-section of a TFT in embodiment 2.

FIGS. 7A to 7D illustrate a method of fabricating the TFT in embodiment 2.

FIGS. 8A to 8C illustrate the method of fabricating the TFT in embodiment 2.

FIG. 9 is a schematic diagram illustrating a cross-section of a TFT in embodiment 3.

FIGS. 10A to 10D illustrate a method of fabricating the TFT in embodiment 3.

FIGS. 11A to 11D illustrate the method of fabricating the TFT in embodiment 3.

FIG. 12 illustrates the method of fabricating the TFT in embodiment 3.

### DESCRIPTION OF EXEMPLARY EMBODIMENTS

### Embodiment 1

### 1A. Structure of TFT

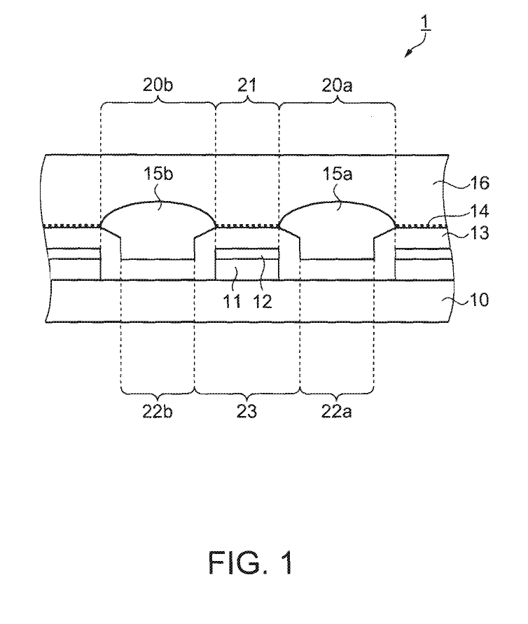

A structure of a TFT 1, which belongs to a bottom gate type, is described here. The TFT 1 in this embodiment is realized as a part of electronic circuits in electronic devices. FIG. 1 is referred to in the descriptions below.

The TFT 1 in FIG. 1 has a glass substrate 10, two indentations 20a, 20b, a protrusion 21 separating the two indentations 20a, 20b from each other, a gate electrode 12, a dielectric layer 13, a source electrode 15a, a drain electrode 15b, an oleophobic or hydrophobic layer 14, and a semiconductor layer 16.

The protrusion 21 is a part of a buffer layer 11, which is described later. On the protrusion 21 is located the gate electrode 12. The indentations 20a, 20b and the protrusion 21 are formed by etching the buffer layer 11 with the gate electrode functioning as an etching mask. As a result of the etching, the boundary of the protrusion 21, which defines the two indentations 20a, 20b, is substantially coincident with that of the gate electrode 12. Each of the two indentations 20a, 20b penetrates the buffer layer 11 and reaches a surface of the glass substrate 10 in this embodiment.

The dielectric layer 13 covers the gate electrode 12 and the indentations 20a, 20b. The dielectric layer 13 is formed by spin-coating a liquid-like material containing a dielectric, so that the dielectric layer 13 defines two indented regions 22a, 22b and a protruding region 23 that respectively correspond to the two indentations 20a, 20b and the protrusion 21. The protruding region 23 has a substantially flat top surface that reflects the shape of the gate electrode 12. In addition, the position of the top surface of the protruding region 23 is substantially coincident with that of the gate electrode 12. Furthermore, the boundary of the top surface of the protruding region 23 corresponds to that of the gate electrode 12.

The depth of the indented regions 22a, 22b may be varied by changing the thickness of the buffer layer 11. Given that the thickness of the dielectric layer 13 is constant, the depth of the indented regions 22a, 22b increases with the thickness of the buffer layer 11. In this embodiment, the source electrode 15a and the drain electrode 15b are to be formed by a liquid process, so the indented regions 22a, 22b are preferably somewhat deep. For this reason, the structure of this embodiment is advantageous in a TFT fabrication process that utilizes the liquid process, since the depth of the indented regions 22a, 22b is increased by forming a thicker buffer layer 11.

The oleophobic or hydrophobic layer 14 is located on the top surface of the protruding region 23. The source electrode 15a and the gate electrode 15b are respectively located in the indented region 22a and the indented region 22b. The overlap between the source electrode 15a and the gate electrode 12 is within a range that is equal to or greater than 10 nm and equal to or less than 10 microns. The overlap between the drain electrode 15b and the gate electrode 12 is also within the range that is equal to or greater than 10 nm and equal to or less than 10 microns. However, these overlaps are not limited to this range and may be, for instance, within a range that is equal to or greater than 0 and equal to or less than 100 microns, since TFTs offering practical performance may be obtained even with the overlaps in this range.

The semiconductor layer 16 covers the source electrode 15a and the drain electrode 15b such that the semiconductor layer 16 in this embodiment is electrically coupled with the source electrode 15a and the drain electrode 15b. Within the semiconductor layer 16, a portion that corresponds to an area between the source electrode 15a and the drain electrode 15b functions as the channel region of the TFT 1.

As described in detail later, since the TFT 1 is designed to have the structure described above, the overlaps between the source electrode 15a and the gate electrode 12 and between the drain electrode 15b and the gate electrode 12 are appropriately controlled even if the fabrication process of the TFT 1 includes a liquid process such as an inkjet process.

### 1B. Method of Fabricating the TFT

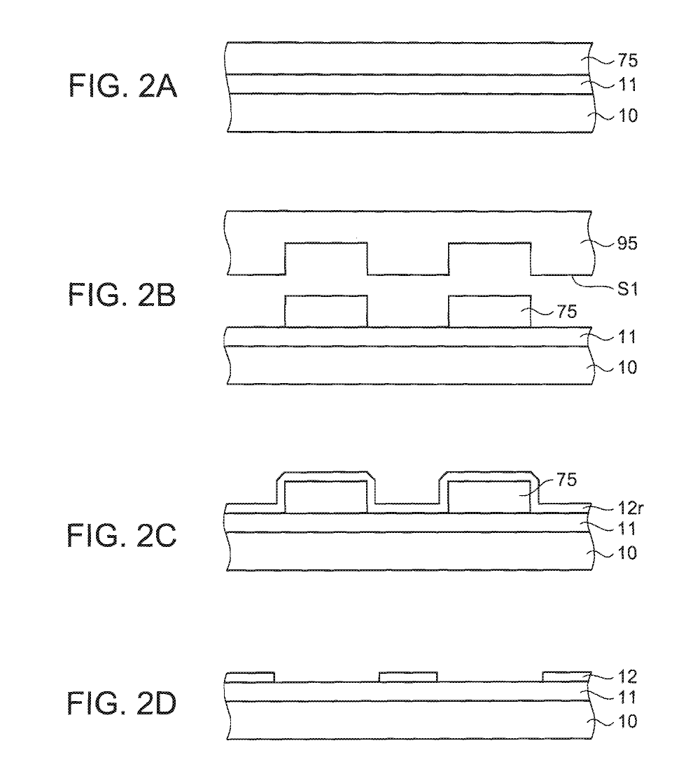

A method of fabricating the TFT 1 is described here. The method of fabricating the TFT 1 in this embodiment is realized as a part of a method of fabricating electronic devices. FIGS. 2 to 4 are referred to in the descriptions below.

First, a buffer layer 11 is formed on a surface of an underlying object (FIG. 2A). Specifically in this embodiment, a material containing PMGI (polymethylglutarimide) is deposited on a glass substrate 10, which is one example of the underlying object, so that a precursor layer containing the PMGI is formed. The thickness of the precursor layer here is about 1 micron. The precursor layer is then heated at a temperature of about 210° C. for 10 minutes so that the buffer layer 11 composed of a PMGI layer is formed.

A gate electrode 12 is then formed on a predetermined portion of the buffer layer 11. In this embodiment, a micro-emboss process is utilized to form the gate electrode 12. Here, the buffer layer 11 is an “underlying layer” for the gate electrode 12.

Specifically, an upper layer 75 composed of a PMMA layer is first formed on the buffer layer 11 by spin-coating and subsequent baking. Meanwhile, a silicon stamp 95 having a surface S1 constituting or defining indentations and a protrusion is prepared (FIG. 28). The indentations are located so as to surround the protrusion of the surface S1. The position of the protrusion of the surface S1 corresponds to that of the gate electrode 12 to be formed.

While the upper layer 75 is heated to a temperature of about 160° C., the silicon stamp 95 is pressed onto the upper layer 75 so that the surface S1 comes into contact with the upper layer 75. After the upper layer 75 is cooled so that the temperature falls to room temperature, the silicon stamp 95 is removed from the upper layer 75. As a result, as shown in FIG. 2B, the upper layer 75 is provided with a pattern defined by an indentation and protrusions. The upper layer 75 at the indentation is then etched by a plasma gas so that a surface of the buffer layer 11 is exposed and becomes the bottom of the indentation. If the surface of the buffer layer 11 is already the bottom of the indentation at the time the silicon stamp 95 is removed, the etching of the upper layer 75 by the plasma gas may be omitted.

After the indentation and protrusions are formed, an aluminum layer 12r is formed on the indentation and the protrusions by an evaporation method such as sputtering or CVD (FIG. 2C). Since the bottom of the indentation is the surface of the buffer layer 11, the aluminum layer 12r is formed so as to cover not only the protrusions but also the surface of the buffer layer 11 at the bottom of the indentation.

After the aluminum layer 12r is formed, the protrusions are submerged in acetone so that these protrusions are removed. As a result, within the aluminum layer 12r portions located on the protrusions are removed along with the protrusions, and thus the gate electrode 12 is lifted off. Namely, the gate electrode 12 is the aluminum layer 12r remaining on the buffer layer 11 at the bottom of the indentation (FIG. 2D).

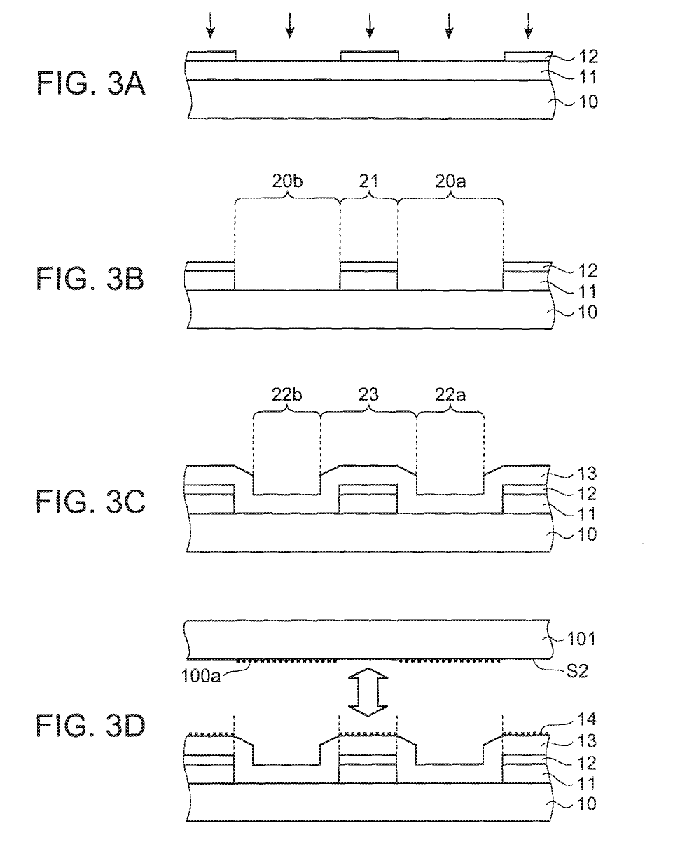

After the gate electrode 12 is formed, the buffer layer 11 is etched with the gate electrode 12 functioning as a mask, as shown in FIG. 3A.

In this embodiment, a plasma etching treatment using a mixture gas of O₂ and CF₄ is applied to the buffer layer 11. Etching yields from the buffer layer 11 a protrusion 21 and indentations 20a, 20b separated from each other by the protrusion 21, the shapes of which are defined by the shape of the gate electrode 12 as shown in FIG. 3B. Here, the etching is conducted until a surface of the glass substrate 10 is exposed and becomes the bottom surfaces of the two indentations 20a, 20b. The gate electrode 12 is finally found on the protrusion 21.

After the buffer layer 11 is etched, a dielectric layer 13 that defines indented regions 22a, 22b and a protruding region 23 is formed, the indented regions 22a, 22b corresponding to the indentations 20a, 20b, and the protruding region 23 corresponding to the protrusion 21, as shown in FIG. 3C.

In this embodiment, a precursor layer containing PVP is formed on the indentations 20a, 20b and the gate electrode 12 by spin-coating. The thickness of the precursor layer is about 1.8 micron. The precursor layer is then baked at a temperature of about 60° C. for about 30 minutes, so that the dielectric layer 13 composed of a PVP layer is obtained. The dielectric layer 13 here is formed in accordance with the shape of the underlying surface defined by the indentations 20a, 20b and the gate electrode 12 on the protrusion 21. As a result, the dielectric layer 13 is found to define the indented regions 22a, 22b corresponding to the indentations 20a, 20b, and the protruding region 23 corresponding to the protrusion 21.

The protruding region 23 thus obtained has a substantially flat top surface that reflects the shape of the gate electrode 12. In addition, the position of the top surface of the protruding region 23 is substantially coincident with that of the gate electrode 12. Moreover, the boundary of the top surface of the protruding region 23 corresponds to that of the gate electrode 12.

After the dielectric layer 13 is formed, an O₂ (oxygen) plasma treatment is applied to the surface of the dielectric layer 13, so that OH groups appears on the surface. The time period for which the O₂ plasma treatment is applied may be short, for instance, equal to or less than 1 minute. The O₂ plasma treatment may be omitted, depending on the material of the dielectric layer 13.

After the O₂ plasma treatment, the top surface of the protruding region 23 is selectively made oleophobic or hydrophobic. In this embodiment, as shown in FIG. 3D, an oleophobic or hydrophobic layer 14 is selectively formed on the top surface of the protruding region 23. A process of forming the oleophobic or hydrophobic layer 14 is as follows.

First, a polydimethylsiloxane (PDMS) stamp 101 having a substantially flat surface S2 is prepared. A material 100a that is to form a self-assembled molecular layer (SAM) is deposited on the surface S2. In this embodiment, the material 100a is 1H,1H,2H,2H-perfluorodecyltrichlorosilane. The surface S2 is then brought close enough to the dielectric layer 13 for the material 100a to contact the top surface of the protruding region 23 without contacting the indented region 22a or the indented region 22b. The material 100a is thereby selectively transferred to the top surface of the protruding region 23. The oleophobic or hydrophobic layer 14 composed of the self-assembled molecular layer (SAM) is thus provided on the top surface of the protruding region 23. The SAM in this embodiment is a monolayer of molecules but may also be a layer consisting of more than monolayer.

Since the indented regions 22a, 22b and the protruding region 23 are formed based on the protrusion 21 that is a part of the buffer layer 11, the gap between the top surface level of the protruding region 23 and the bottom surface level of the indented regions 22a, 22b is large. For this reason, the top surface of the protruding region 23 is provided with the oleophobic or hydrophobic layer 14 with high selectivity by a soft contact printing method, even if the surface S2 of the stamp 101 is not sufficiently even.

On the other hand, the inside of the indented regions 22a, 22b is oleophilic or hydro-philic due to the O₂ plasma treatment. Accordingly, there is a difference, or contrast, in wettability between the inside of the indented regions 22a, 22b and the top surface of the protruding region 23.

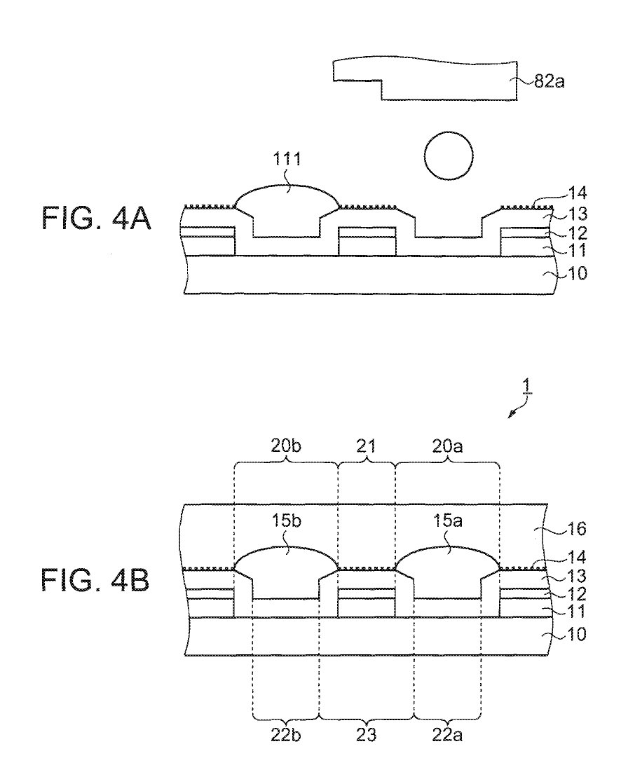

After the top surface of the protruding region 23 is made oleophobic or hydrophobic, a functional liquid 111 containing an electrically conductive material is provided in the indented regions 22a, 22b. In this embodiment, the functional liquid 111 is a water-based colloidal suspension of poly(3,4-ethylene-dioxythiophene) (PEDOT) doped with poly(styrene sulphonic acid) (PSS). The functional liquid 111 is discharged from an inkjet head 82a and deposited in the indented regions 22a, 22b (FIG. 4A).

Since the top surface of the protruding region 23 is oleophobic or hydrophobic, the functional liquid 111 provided in the respective indented regions 22a, 22b stops spreading at the boundary of the top surface of the protruding region 23. The boundary of the top surface of the protruding region 23 corresponds to that of the gate electrode 12, so the functional liquid 111 that is thus provided becomes aligned with the gate electrode 12. In addition, since the top surface of the protruding region 23 is oleophobic or hydrophobic, the functional liquid 111 does not bridge the area between the indented regions 22a, 22b.

The term “functional liquid” refers to a liquid material or a liquid-like material with a level of viscosity that allows it to be discharged as droplets from the nozzles of the inkjet head 82a. Here, the functional liquid may be aqueous or oil-like, provided it flows sufficiently (or has sufficiently low viscosity) to be discharged from the nozzles. The functional liquid may contain a solid material as long as the functional liquid maintains overall flowability. The viscosity of the functional liquid is preferably within a range that is equal to or greater than 1 mPa·s and equal to or less than 50 mPa·s. If the viscosity is 1 mPa·s or higher, the circumference of the nozzles is scarcely contaminated with the functional liquid when it is discharged as droplets. Meanwhile, if the viscosity is 50 mPa·s or lower, the droplets may be discharged more smoothly because the nozzles clog less frequently.

The functional liquid 111 provided in the indented regions 22a, 22b is dried at a temperature of about 60° C. for about 30 minutes. As a result, a source electrode 15a and a drain electrode 15b containing the PEDOT are obtained in the indented regions 22a, 22b. As mentioned above, since the functional liquid 111 is aligned with the gate electrode 12, each of the source electrode 15a and the drain electrode 15b, which are obtained from the functional liquid 111, is aligned with the gate electrode 12. In this embodiment, the overlap between the source electrode 15a and the gate electrode 12 is within the range that is equal to or greater than 10 nm and equal to or less than 10 microns. Similarly, the overlap between the drain electrode 15b and the gate electrode 12 is within the range that is equal to or greater than 10 nm and equal to or less than 10 microns.

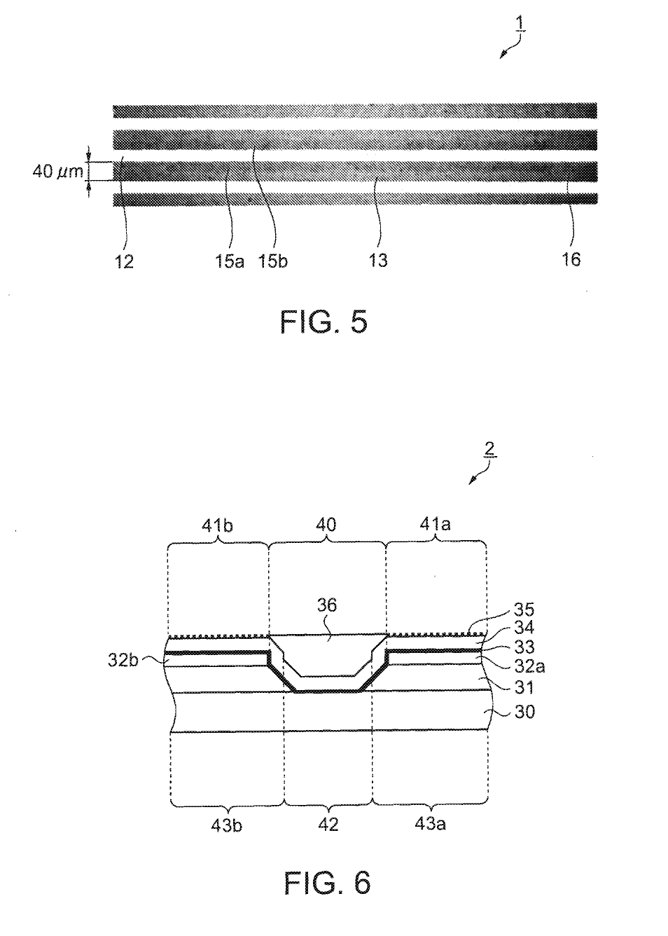

Next, a CF₄ plasma treatment is applied to the surface of the dielectric layer 13 so as to modify it. A semiconductor layer 16 composed of a polyarylamine (PAA) layer or a polythiophene layer is then formed on the dielectric layer 13, the source electrode 15a and the drain electrode 15b by spin-coating polyarylamine or polythiophene. This results in the TFT 1 shown in FIGS. 4B and 5. The TFT 1 that is thus obtained exhibits good performance.

Modifications of (1)

In embodiment 1, the gate electrode 12 is located on a predetermined portion of the buffer layer 11. However, instead of this structure, the gate electrode 12 may be located on a predetermined portion of the glass substrate 10. In this case, the buffer layer 11 is omitted, and the surface of the glass substrate 10 is processed to define the protrusion 21 and the two indentations 20a, 20b separated from each other by the protrusion 21. The glass substrate 10 itself is the underlying layer for the gate electrode 12 in this case.

The TFT of such a structure is fabricated, for instance, by a method including a step of etching the glass substrate 10 by a water solution containing 5% HF with the gate electrode 12 functioning as a mask. Etching continues until the indentations 20a, 20b are etched in the glass substrate 10 to a depth of 0.8 micron.

(2) In embodiment 1, the underlying layer for the gate electrode 12 is etched. However, the underlying layer does not need to be etched if the gate electrode 12 is thick enough to create height difference sufficient to enable the top surface of the protruding regions 23 (FIG. 1) to be selectively made oleophobic or hydrophobic by soft-contact printing.

### Embodiment 2

### 2A. Structure of TFT

A structure of a TFT 2, which belongs to a top gate type, is described here. The TFT 2 in this embodiment is realized as a part of electronic circuits in electronic devices. FIG. 6 is referred to in the descriptions below.

The TFT 2 in FIG. 6 has a glass substrate 30, protrusions 41a, 41b located on the glass substrate 30, an indentation 40 defined in an area between the protrusions 41a, 41b, a source electrode 32a, a drain electrode 32b, a semiconductor layer 33, a dielectric layer 34, an oleophobic or hydrophobic layers 35 and a gate electrode 36.

Each of the protrusions 41a, 41b is a part of a buffer layer 31 that is described later. The source electrode 32a and the drain electrode 32b are respectively located on the protrusions 41a, 41b. The protrusions 41a, 41b and the indentation 40 are formed by etching the buffer layer 31 with the source electrode 32a and the drain electrode 32b functioning as masks. Consequently, the boundaries of the protrusions 41a, 41b—and, likewise, the boundary that defines the indentation 40—correspond to the boundaries of the source electrode 32a and the drain electrode 32b. The indentation 40 penetrates the buffer layer 31 and reaches a surface of the glass substrate 30 in this embodiment.

The semiconductor layer 33 covers the source electrode 32a, the drain electrode 32b and the indentation 40 such that the semiconductor layer 33 in this embodiment is electrically coupled with the source electrode 32a and the drain electrode 32b. The semiconductor layer 33 is formed by spin-coating a material containing a semiconductor material, so the surface of the semiconductor layer 33 reflects the shapes of the protrusions 41a, 41b and the indentation 40. Within the semiconductor layer 33, a portion that corresponds to an area between the source electrode 32a and the drain electrode 32b functions as the channel region of the TFT 2

The dielectric layer 34 covers semiconductor layer 33. The dielectric layer 34 is formed by spin-coating a material containing a dielectric, so that the dielectric layer 34 defines protruding regions 43a, 43b corresponding to the protrusions 41a, 41b, and an indented region 42 corresponding to the indentation 40. The protruding regions 43a, 43b here have substantially flat top surfaces that reflect the shapes of the source electrode 32a and the drain electrode 32b. Moreover, the positions of the protruding regions 43a, 43b are substantially coincident with those of the source electrode 32a and the drain electrode 32b. The boundaries of the protruding regions 43a, 43b correspond to those of the source electrode 32a and the drain electrode 32b.

The depth of the indented region 42 may be varied by changing the thickness of the buffer layer 31. For instance, given that the total thickness of the semiconductor layer 33 and the dielectric layer 34 is constant, the depth of the indented region 42 increases with the thickness of the buffer layer 31. In this embodiment, the gate electrode 42 is formed by a liquid process in the indented region 42, so the indented region 42 is preferably somewhat deep. For this reason, the structure of this embodiment is advantageous in a TFT fabrication process that utilizes the liquid process, since the depth of the indented region 42 is increased by forming a thicker buffer layer 31.

The oleophobic or hydrophobic layers 35 are located on the top surfaces of the protruding regions 43a, 43b. The gate electrode 36 is located in the indented region 42. The overlap between the source electrode 32a and the gate electrode 36 is within the range that is equal to or greater than 10 nm and equal to or less than 10 microns. The overlap between the drain electrode 32b and the gate electrode 36 is also within the range that is equal to or greater than 10 nm and equal to or less than 10 microns. However, these overlaps are not limited to that range and may be, for instance, within a range that is equal to or greater than 0 and equal to or less than 100 microns, since TFTs offering practical performance may be obtained even with the overlaps in this range.

As described later, since the TFT 2 has the structure mentioned above, the overlaps between the source electrode 32a and the gate electrode 36 and between the drain electrode 32b and the gate electrode 36 are appropriately adjusted even where a TFT fabrication process includes a liquid process such as an inkjet process.

### 2B. Method of Fabricating the TFT

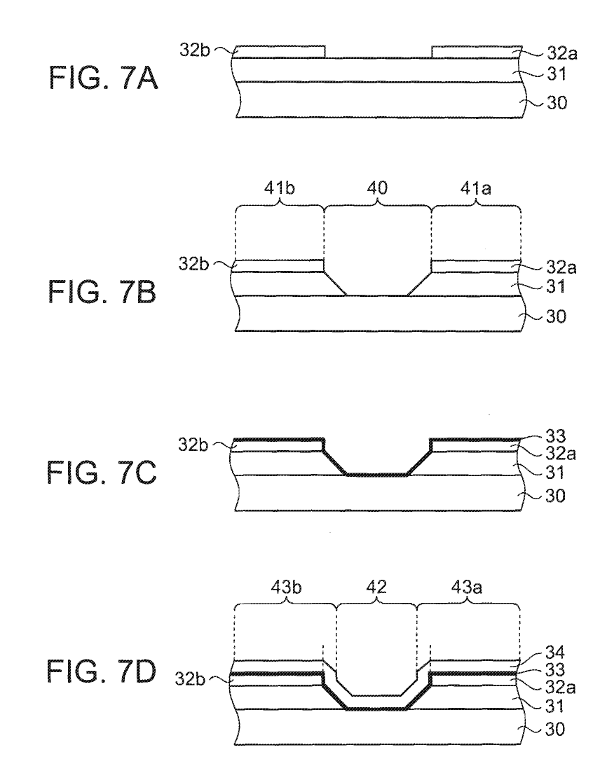

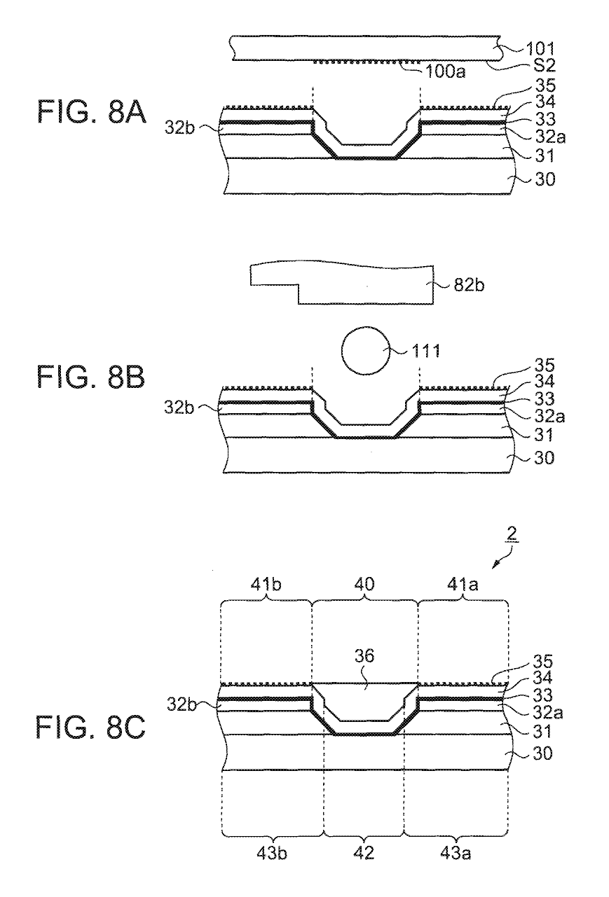

A method of fabricating the TFT 2 is described here. The method of fabricating the TFT 2 in this embodiment is realized as a part of a method of fabricating electronic devices. FIGS. 7 and 8 are referred to in the descriptions below.

First, a buffer layer 31 is formed on a glass substrate 30 in a way similar to that of embodiment 1. A source electrode 32a and a drain electrode 32b separated from each other are formed by a photolithography method on respective portions of the buffer layer 31 (FIG. 7A). The buffer layer 31 is the “underlying layer” for the source electrode 32a and the drain electrode 32b.

The buffer layer 31 is then etched, with the source electrode 32a and the drain electrode 32b functioning as masks (FIG. 7B). The portion of the buffer layer 31 covered by the source electrode 32a remains, forming a protrusion 41a. The portion of the buffer layer 31 covered by the drain electrode 32b remains, forming a protrusion 41b. An indentation 40 appears between the protrusions 41a, 41b. The buffer layer 31 is etched until a surface of the glass substrate 30 is exposed at the bottom of the indentation 40.

A semiconductor layer 33 is then formed on the source electrode 32a, the indentation 40 and the drain electrode 32b by spin-coating a material containing a semiconductor material and by subsequent baking (FIG. 7C). Since the semiconductor layer 33 here is formed such that it matches the shape of the underlying surface defined by the indentation 40, the source electrode 32a and the drain electrode 32b on the protrusions 41a, 41b, the surface of the semiconductor layer 33 defines an indentation and protrusions that reflect or correspond to the indentation 40 and the protrusions 41a, 41b.

Next, a material containing a dielectric is spin-coated on the semiconductor layer 33, and then baked (FIG. 7D). A dielectric layer 34 is thus formed on the semiconductor layer 33. The dielectric layer 34 here is formed along the indentation and the protrusions defined by the surface of the semiconductor layer 33, and thus the dielectric layer 34 defines an indented region 42 corresponding to the indentation 40, and protruding regions 43a, 43b corresponding to the protrusions 41a, 41b.

The protruding regions 43a, 43b have substantially flat top surfaces that reflect the shapes of the source electrode 32a and the drain electrode 32b. The position of the top surface of the protruding region 43a is substantially coincident with that of the source electrode 32a. In addition, the boundary of the top surface of the protruding region 43a corresponds to that of the source electrode 32a. Meanwhile, the position of the top surface of the protruding region 43b is substantially coincident with that of the drain electrode 32b. In addition, the boundary of the top surface of the protruding region 43b corresponds to that of the drain electrode 32b.

The top surfaces of the protruding regions 43a, 43b are then made oleophobic or hydrophobic. In this embodiment, as shown in FIG. 8A, oleophobic or hydrophobic layers 35 are formed on the top surfaces of the protruding regions 43a, 43b. The process of forming the oleophobic or hydrophobic layers 35 is basically the same as that of the oleophobic or hydrophobic layer 14 in embodiment 1.

Since the protruding regions 43a, 43b and the indented region 42 are formed based on the protrusions 41a, 41b that are part of the buffer layer 31, the gap between the top surface level of the protruding regions 43a, 43b and the bottom surface level of the indented region 42 is relatively large. For this reason, even if the surface S2 (FIG. 8A) of the stamp 101 is not very even, the oleophobic or hydrophobic layers 35 are provided on the top surfaces of the protruding regions 43a, 43b with high selectivity by soft-contact printing.

After the top surfaces of the protruding regions 43a, 43b are made oleophobic or hydrophobic, a functional material 111 containing an electrically conductive material is provided in the indented region 42 (FIG. 8B). In this embodiment, the functional liquid 111 is a liquid-like material containing silver nano-particles. The functional liquid 111 is discharged from an inkjet head 82b and deposited in the indented region 42.

Since the top surfaces of the protruding regions 43a, 43b are oleophobic or hydrophobic, the functional liquid 111 provided in the indented region 42 stops spreading at the boundaries of the top surfaces of the protruding regions 43a, 43b. The boundaries of the top surfaces of the protruding region 43a, 43b substantially correspond to those of the source electrode 32a and the drain electrode 32b, so the functional liquid 111 that is deposited aligns with the source electrode 32a and the drain electrode 32b.

After the functional liquid 111 is provided in the indented region 42, it is heated so that a gate electrode 36 containing the silver is formed in the indented region 42. Since the functional liquid 111 in the indented region 42 is aligned with the source electrode 32a and the drain electrode 32b, the gate electrode 36 formed from the functional liquid 111 aligns with the source electrode 32a and the drain electrode 32b. The overlap between the source electrode 32a and the gate electrode 36 is within a range that is equal to or greater than 10 nm and equal to or less than 10 microns. The overlap between the drain electrode 32b and the gate electrode 36 is also in the range that is equal to or greater than 10 nm and equal to or less than 10 microns. The TFT 2 in this embodiment is thus fabricated.

Modifications of Embodiment 2

(1) According to embodiment 2, the source electrode 32a and the drain electrode 32b are located on the two portions of the buffer layer 31. However, instead of this structure, the source electrode 32a and the drain electrode 32b may be, for instance, located on two portions of the glass substrate 30. In this case, a surface of the glass substrate 30 is processed so as to define the two protrusions 41a, 41b and the indentation 40 defined by an area between the two protrusions 41a, 41b. The glass substrate 30 itself is the “underlying layer” for the source electrode 32a and the drain electrode 32b in this case. A method of fabricating the TFT having such a structure is described below.

First, a source electrode and a drain electrode composed of Indium-Tin-Oxide (ITO) are formed on the glass substrate 30 according to a photolithography method. The glass substrate 30 is then etched by a water-based solution containing 5% HF with the source electrode and the drain electrode functioning as masks. Etching continues until an indentation is etched in the glass substrate 30 to a depth of 0.8 micron. The two protrusions and the indentation defined by an area between the two protrusions are thus provided in the surface of the glass substrate 30. The two protrusions here are the portions of the glass substrate 30, the portions being covered with the source electrode and the drain electrode.

A semiconductor layer composed of a PAA layer or a polythiophene layer having a thickness of about 50 nm is then formed on the source electrode, the indentation and the drain electrode. In addition, a dielectric layer composed of a PVP layer having a thickness of about 1.5 micron is formed on the semiconductor layer. This dielectric layer defines an indented region and two protruding regions respectively corresponding to the indentation and the two protrusions.

The two protruding regions have substantially flat top surfaces that reflect the shapes of the source electrode and the drain electrode. The positions of the top surfaces of the two protruding regions are coincident with those of the source electrode and the drain electrode. The boundaries of the top surfaces of the two protruding regions correspond to those of the source electrode and the drain electrode.

Next, an O₂ plasma treatment is applied to the surface of the dielectric layer, making the top surfaces of the two protruding regions oleophobic or hydrophobic. In this modification, oleophobic or hydrophobic layers composed of a self-assembled molecular layer are formed on the top surfaces of the two protruding regions.

A functional liquid is then provided in the indented region, the functional liquid here being a water-based PEDOT-PSS colloidal suspension. The functional liquid is then heated so that a gate electrode is formed in the indented region. The TFT in this modification is thus fabricated.

(2) In embodiment 2, the underlying layer for the source electrode 32a and the drain electrode 32b is etched. However, the underlying layer is need not be etched if the source electrode 32a and the drain electrode 32b are thick enough to create a height difference that enables the top surfaces of the protruding regions 43a, 43b (FIG. 6) to be selectively made oleophobic or hydrophobic by soft-contact printing.

### Embodiment 3

A method of fabricating a TFT in which the overlaps between the gate electrode and the source/drain electrodes may be optimized so as to improve the carrier injection is described below.

### 3A. Structure of TFT

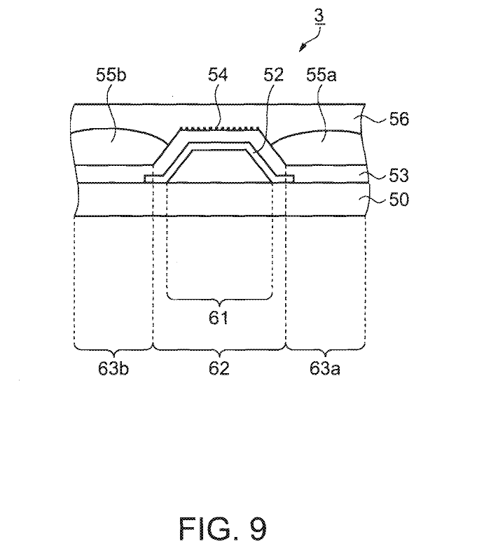

A structure of a TFT 3, which belongs to a bottom gate type, is described here. The TFT3 is realized as a part of electronic circuits in electronic devices. FIG. 9 is referred to in the descriptions below.

The TFT 3 in FIG. 9 has a glass substrate 50, a tapered protrusion 61 located on the glass substrate 50, a gate electrode 52, a dielectric layer 53, an oleophobic or hydrophobic layer 54, a source electrode 55a, a drain electrode 55b and a semiconductor layer 56.

The tapered protrusion 61 is a part of a lower layer 51 that is described in detail later. The tapered protrusion 61 has a bottom surface and a top surface, the bottom surface facing the side of the glass substrate 50. The tapered protrusion 61 is shaped such that the area of the top surface is smaller than that of the bottom surface. The top surface of the tapered protrusion 61 is substantially flat. The gate electrode 52 is provided on the tapered protrusion 61 along the shape of the tapered protrusion 61.

The dielectric layer 53 covers the gate electrode 52 so as to be along the gate electrode 52. The dielectric layer 53 reflects the shape of the tapered protrusion 61, and thus the dielectric layer 53 defines a tapered protrusion 62 corresponding to the tapered protrusion 61. Moreover, two regions 63a, 63b are defined so as to be separated from each other by the tapered protrusion 62. The tapered protrusion 62 has a substantially flat top surface that reflects the shape of the gate electrode 52. The position of the top surface of the tapered protrusion 62 is substantially coincident with that of the gate electrode 52. The boundary of the top surface of the tapered protrusion 62 corresponds to that of the gate electrode 52.

The oleophobic or hydrophobic layer 54 is located on the top surface of the tapered protrusion 62. The source electrode 55a is located in the region 63a, and the drain electrode 55b is located in the region 63b.

The shape of the gate electrode 52 is tapered, and the shape of the tapered protrusion 62 is also tapered due to the shape of the gate electrode 52. Since the source electrode 55a and the drain electrode 55b are to be formed from a functional liquid, these tapers enables the overlaps with the gate electrode 52 to be adjusted by varying the amount of the functional liquid provided in the regions 63a and 63b during the fabrication process of the TFT 3.

The semiconductor layer 56 covers the source electrode 56a and the drain electrode 56b such that the semiconductor layer 56 is electrically coupled with the source electrode 56a and the drain electrode 56b. Within the semiconductor layer 56, a portion that corresponds to an area between the source electrode 56a and the drain electrode 56b functions as the channel region of the TFT 3.

### 3B. Method of Fabric

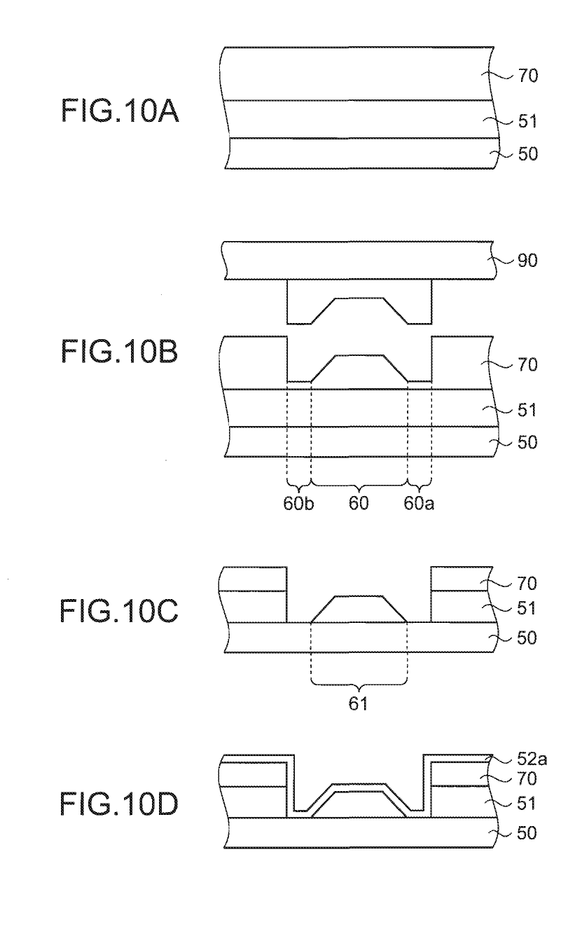

A method of fabricating the TFT 3 is described here. The method of fabricating the TFT 3 in this embodiment is realized as a part of a method of fabricating electronic devices. FIGS. 10 to 12 are referred to in the descriptions below.

First, a double layer structure, or a multi-layer structure, including a lower layer 51 and an upper layer 70 is formed on a glass substrate 50 (FIG. 10A).

In this embodiment, a precursor layer containing PMGI is formed by spin-coating a material containing the PMGI on the glass substrate 50. The thickness of the precursor layer here is about 1 micron. The precursor layer is then heated at a temperature of about 210° C. for about 10 minutes, so that the lower layer 51 composed of a PMGI layer is formed Then, a precursor layer containing PMMA is formed by spin-coating a material containing the PMMA on the lower layer 51. The thickness of the precursor layer here is about 1.5 micron. The precursor layer is then heated so that the upper layer 70 containing the PMMA is formed. The glass substrate 50 here is the “underlying layer” for the lower layer 51

After the double layer structure is formed, the upper layer 70 is embossed with a stamp having a surface defining a “pi” shape. The embossing is conducted at a temperature of about 160° C. Two indentations 60a, 60b and a tapered protrusion 60 embossed between the two indentations 60a, 60b are thus provided in the upper layer 70 (FIG. 10B). Specifically, the tapered protrusion 60 has a substantially flat top surface and two slopes that rise from the lower layer 51 side to the top surface. These two slopes also face respective sides opposite to each other.

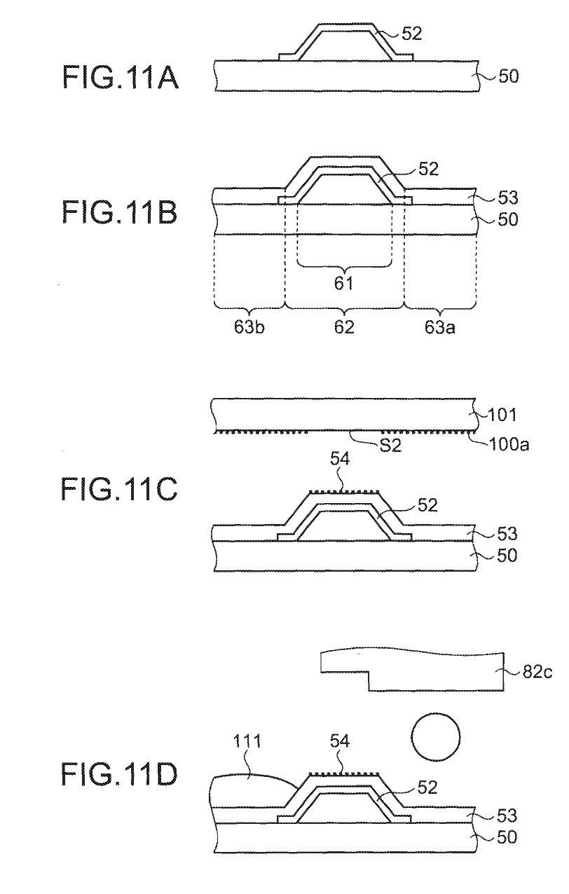

The lower layer 51 is etched, with the upper layer 70 functioning as a mask, so that the shape of the tapered protrusion 60 is transferred from the upper layer 70 to the lower layer 51. The tapered protrusion 61 corresponding to the tapered protrusion 60 is thus provided in the lower layer 51 (FIG. 11G). The etching here is a plasma etching using a mixture gas of O₂ and CF₄ where the ratio between O₂ and CF₄ is 3:2.

In this embodiment, the upper layer 70 is substantially removed at portions of the two indentations 60a, 60b and the tapered protrusion 60 by the etching (FIG. 10C). Meanwhile, the upper layer 70 remains at portions other than the indentation 60a, 60b or the tapered protrusion 60. The tapered protrusion 61 has basically the same tapered shape as the tapered protrusion 60. Namely, the tapered protrusion 61 has a top surface that is substantially flat and two slopes that rise from the glass substrate 50 side to the top surface. These two slopes also face respective sides opposite to each other.

After the tapered protrusion 61 is formed, an electrically conductive layer 52a is formed at least on the tapered protrusion 61 (FIG. 10D). In this embodiment, the electrically conductive layer 52a composed of aluminum is formed by aluminum evaporation. The aluminum evaporation process forms the electrically conductive layer 52a not only on the tapered protrusion 61 but also on the upper layer 70 that is remaining.

The remaining upper layer 70 is then removed in an appropriate solvent (not shown). The electrically conductive layer 52a on the upper layer 70 is removed along with the upper layer 70, and thus the electrically conductive layer 52a on the tapered protrusion 61 is lifted off as a gate electrode 52. The solvent in this embodiment is acetone.

Dry etching is then applied to the lower layer 51 with the gate electrode 52 functioning as a mask. Within the lower layer 51, a portion that constitutes the tapered protrusion 61 remains since it is covered with the gate electrode 52, while the other portions of the lower layer 51 are removed by the etching process. Therefore, a surface of the glass substrate 50 is exposed at portions other than the gate electrode 52 (FIG. 11A). The dry etching here is a plasma etching treatment using the above-mentioned mixture gas of O₂ and CF₄ where the ratio between O₂ and CF₄ is 3:2.

The gate electrode 52 is formed so as to be along the shape of the tapered protrusion 61. As a result, the gate electrode 52 has a top surface that is substantially flat and two slopes that rise from the glass substrate 50 side to the top surface. These two slopes also face respective sides opposite to each other.

After the dry etching, the surfaces of the gate electrode 52 and the glass substrate 50 are cleaned with isopropanol.

A dielectric layer 53 is then spin-coated on the gate electrode 52 and the glass substrate 50 (FIG. 11B). The thickness of the dielectric layer 53 is about 1.5 micron. The dielectric layer 53 thus defines a tapered protrusion 62 formed along the gate electrode 52, and two regions 63a, 63b separated from each other by the tapered protrusion 62. The tapered protrusion 62 is tapered basically in the same shape as the tapered protrusions 60, 61. Hence, the tapered protrusion 62 has a top surface that is substantially flat and two slopes that rise from the glass substrate 50 side to the top surface. These two slopes also face respective sides opposite to each other.

After the dielectric layer 53 is formed, an O₂ plasma treatment is applied to the surface of the dielectric layer 53 for a short time period.

Next, the top surface of the tapered protrusion 62 is selectively made oleophobic or hydrophobic. In this embodiment, an oleophobic or hydrophobic layer 54 is selectively provided on the top surface of the tapered protrusion 62 by soft-contact printing. Specifically, the same material 100a as embodiment 1 is transferred to the top surface of the tapered protrusion 62 by the stamp 101 having the surface S2 (FIG. 3D) in the same way as embodiment 1. Thus, the material 100a is selectively transferred to the top surface of the tapered protrusion 62. Accordingly, the oleophobic or hydrophobic layer 54 composed of the self-assembled molecular layer is provided on the top surface of the tapered protrusion 62 (FIG. 11C).

Since the tapered protrusion 62 is formed based on the tapered protrusion 61, which is a part of the lower layer 51, the gap between the top surface level of the tapered protrusion 62 and the level of the regions 63a, 63b is large. For this reason, even if the surface S2 of the stamp 101 is not very even, the oleophobic or hydrophobic layer 54 is selectively provided on the top surface of the tapered protrusion 62 by soft-contact printing.

Next, a functional liquid 111 containing an electrically conductive material is provided to the regions 63a, 63b (FIG. 11D). In this embodiment, the functional liquid 111 is a water-based colloidal suspension of PEDOT and PSS. The functional liquid 111 is discharged from an inkjet head 82c and deposited in the region 63a, 63b. Since there is the oleophobic or hydrophobic layer 54 on the top surface of the tapered protrusion 62, the functional liquid 111 does not bridge an area across the tapered protrusion 62.

The functional liquid 111 that is provided in the respective regions 63a, 63b is then heated at a temperature of about 60° C. for about 30 minutes. This leads to a source electrode 55a and a drain electrode 55b containing the PEDOT.

In this embodiment, if the amount of the functional liquid 111 that is provided to the region 63a varies, an area of the overlap between the functional liquid 111 and the gate electrode 56 with one of the slopes of the tapered protrusion 62 interposed therebetween varies accordingly. Therefore, the overlap between the source electrode 55a and the gate electrode 52 may be optimized by adjusting the amount of the functional liquid 111 that is provided to the region 63a. Moreover, for the same reason, the overlap between the drain electrode 55b and the gate electrode 52 may be optimized by adjusting the amount of the functional liquid 111 that is provided to the region 63b. Therefore, the carrier injection of the TFT 3 may be improved.

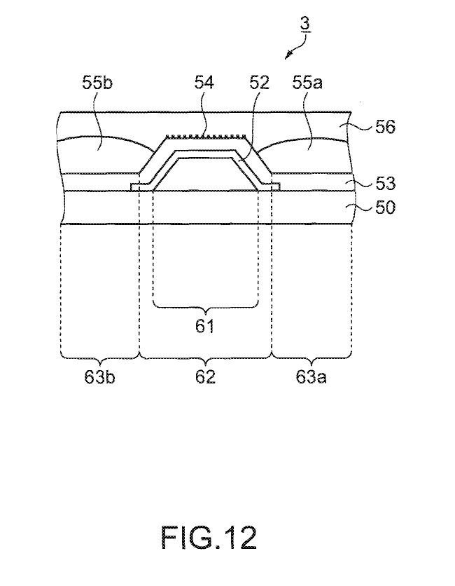

A CF₄ plasma treatment is then applied to modify the surface of the dielectric layer 53. After that, a semiconductor layer 56 that covers the source electrode 55a and the drain electrode 55b is formed. The TFT 3 in this embodiment 3 is thus fabricated (FIG. 12).

Modification 1

In embodiments 1 to 3, the methods of fabricating TFTs are realized as a part of the method of fabricating electronic devices. However, these methods of fabricating TFTs may be realized as a part of a method of fabricating electronic circuits, or electronic apparatus. The term “electronic device” includes at least one of, for instance, a ferroelectric device, a light emitting diode, a thin film transistor, an electrochemical cell and a photovoltaic cell. The term “electronic apparatus” includes at least one of, for instance, a liquid crystal display device, a plasma display device, an FED (field emission display), an SED (surface-conduction electron-emitter display), an OLED and an electrophoretic display device.

Modification 2

In embodiments 1 to 3, the glass substrates 10, 30, 50 are described as an example of a substrate. However, instead of these glass substrates 10, 30, 50, at least one of a ceramic substrate, an epoxy substrate, a glass-epoxy substrate and a silicon substrate may be used with basically the same advantages as embodiments 1 to 3.

Modification 3

In embodiments 1 to 3, spin-coating is used to provide materials on underlying surfaces. However, instead of spin-coating, at least one of, for instance, doctor blading, printing (e.g. screen printing, offset printing, flexo printing, pad printing, inkjet printing), evaporation, sputtering, chemical vapour deposition, dip- and spray coating, spin-coating, and electroless plating may also be utilized.

Modification 4

In embodiments 1 to 3, a SAM formation process or a plasma treatment is conducted as a surface modification process. However, instead of the SAM formation process or the plasma treatment, at least one of, for instance, a corona discharge treatment, a UV-ozone treatment, a wet-chemical treatment and single- and multi-layer coating may be conducted.

Modification 5

In embodiments 1 to 3, plasma etching is used, but wet chemical etching may be conducted instead.

Modification 6

In embodiment 1, the step of forming the gate electrode 12 includes a micro-emboss process. However, instead of the micro-emboss process, the step of forming the gate electrode 12 includes at least one of, for instance, soft-contact printing, photo-lithography, nano-imprinting, optical interference, off-set printing and screen printing. The step of forming the source electrode 32a and the drain electrode 32b in embodiment 2 may be modified in basically the same way as the gate electrode 12.

Modification 7

In embodiments 1 and 2, the functional liquid 111 is a water-based colloidal suspension containing PEDOT and PSS. However, instead of such a colloidal suspension, the functional liquid 111 may be at least one of, for instance, a solution containing a dissolved organic material or inorganic material, and an organic solution or inorganic solution-based colloidal suspension.

Modification 8

The functional liquid 111 in embodiments 1 to 3 may contain surfactants in addition to the electrically conductive material. If the functional liquid 111 contains the surfactants, an area between a plurality of electrically conductive patterns, for instance, the source electrode 15a and the drain electrode 15b (FIG. 1), which are formed from the functional material 111, is prevented from being bridged by the functional liquid 111 or droplets thereof. Accordingly, an electrical short-circuit between the electrically conductive patterns is prevented.

Modification 9

As a material 100a for the oleophobic or hydrophobic layers 14, 35, 54, at least one of fluoroalkylsilane (FAS) and polymers containing fluorine may be used.

In the case of FAS, when the FAS molecules bond to an underlying surface, they are oriented to form a self-assembled molecular layer in which their fluoroalkyl groups position so as to constitute a free surface of the self-assembled molecular layer. The surface energy of the surface of the FAS film (the self-assembled molecular layer), which consists of the thus arranged fluoroalkyl groups, is relatively small, and thus the surface is oleophobic or hydrophobic. Forming the FAS film on the underlying surface thus provides the oleophobic or hydrophobic character to the underlying surface. Moreover, the FAS film is highly durable since it strongly adheres to the underlying surface.

FAS includes fluoroalkylsilane such as heptadecafluoro-1,1,2,2 tetrahydrodecyltriethoxysilane, heptadecafluoro-1,1,2,2 tetrahydrodecyltrimethoxysilane, heptadecafluoro-1,1,2,2 tetrahydrodecyltrichlorosilane, tridecanfluoro-1,1,2,2 tetrahydrooctyltriethoxysilane tridecanfluoro-1,1,2,2 tetrahydrooctyltrimethoxysilane, tridecanfluoro-1,1,2,2 tetrahydrooctyltrichlorosilane and trifluoropropyltrimethoxysilane. In use, one of the above compounds may be used independently, or two or more kinds of compounds may be used.

The foregoing descriptions has been given by way of example only and it will be appreciated by a person skill in the art that more modifications can also be made without departing from the scope of the invention.

What is claimed is:

1. A transistor, comprising:
an underlying layer;
a gate electrode located over the underlying layer;
a dielectric layer covering the gate electrode so as to define two indented regions and a protruding region separating the two indented regions from each other;
an oleophobic or hydrophobic layer formed on a top surface of the protruding region;
a source electrode and a drain electrode formed in the two indented regions; and
a semiconductor layer that is electrically coupled with the source electrode and the drain electrode.

2. The transistor according to claim 1, the source electrode and the drain electrode being formed by providing a functional liquid containing a conductive material in the two indented regions and heating or drying the functional liquid in the two indented regions.

3. The transistor according to claim 1, the oleophobic or hydrophobic layer being a self-assembled molecular layer.

4. The transistor according to claim 1, the oleophobic or hydrophobic layer including a polymer containing fluorine.

5. An electronic circuit comprising a transistor according to claim 1.

6. An electronic device comprising a transistor according to claim 1.

7. An electronic apparatus comprising a transistor according to claim 1.

8. A transistor, comprising:
an underlying layer;
a source electrode and a drain electrode located over the underlying layer;
a semiconductor layer that is electrically coupled with the source electrode and the drain electrode and that defines two protrusions and an indentation;
a dielectric layer formed on the semiconductor layer so as to define two protruding regions and an indented region respectively corresponding to the two protrusions and the indentation;
oleophobic or hydrophobic layers formed on top surfaces of the two protruding regions; and
a gate electrode formed in the indented region.

9. The transistor according to claim 8, the gate electrode being formed by providing a functional liquid containing a conductive material in the indented region and heating or drying the functional liquid in the two indented regions.

10. The transistoaccording to claim 8, wherein each of the oleophobic or hydrophobic layers being a self-assembled molecular layer.

11. The transistoaccording to claim 8, the oleophobic or hydrophobic layers including a polymer containing fluorine.

12. An electronic circuit comprising a transistor according to claim 8.

13. An electronic device comprising a transistor according to claim 8.

14. An electronic apparatus comprising a transistor according to claim 8.

15. A transistor, comprising:
an underlying layer;
a first tapered protrusion located over the underlying layer;
a gate electrode formed along the first tapered protrusion;
a dielectric layer covering the gate electrode so as to define a second tapered protrusion;
an oleophobic or hydrophobic layer formed on a top surface of the second tapered protrusion;
a source electrode and a drain electrode formed so as to be in contact with respective two slopes of the second tapered protrusion, the two slopes facing opposite sides to each other; and
a semiconductor layer that is electrically coupled with the source electrode and the drain electrode.

16. The transistoaccording to claim 15, the source electrode and the drain electrode being formed by providing a functional liquid containing a conductive material in the two regions separated by the second tapered protrusion and heating or drying the functional liquid in the two regions.

17. The transistoaccording to claim 15, the oleophobic or hydrophobic layer being a self-assembled molecular layer.

18. The transistoaccording to claim 15, the oleophobic or hydrophobic layer including a polymer containing fluorine.

19. An electronic circuit comprising a transistor according to claim 15.

20. An electronic device comprising a transistor according to claim 15.
